(19) United States
(12) Patent Application Publication
(10) Pub. No.: US 2026/0247690 A1
(43) Pub. Date: Aug. 20, 2026

(54) SEMICONDUCTOR DEVICE

(71) Applicant: FUJI ELECTRIC CO., LTD., Kanagawa (JP)

(72) Inventors: Shotaro HIGUCHI, Matsumoto-city (JP); Tatsuya NAITO, Matsumoto-city (JP)

(21) Appl. No.: 19/433,072

(22) Filed: Dec. 26, 2025

(30) Foreign Application Priority Data
Feb. 19, 2025 (JP) 2025-025382

(51) Int. Cl. H10D 84/00; H10D 12/00; H10D 62/10; H10D 62/17

(52) U.S. Cl. CPC H10D 84/161; H10D 12/481; H10D 62/126; H10D 62/393

(57) ABSTRACT

Provided is a semiconductor substrate with a transistor portion and a diode portion, wherein the plurality of trench portions have a plurality of gate trench portions and a plurality of dummy trench portions; and wherein the transistor portion has: a main region; and a boundary contact region, provided closer to the diode portion than to the main region, where an area proportion of contact holes provided in the interlayer dielectric film above a mesa portion is greater than that of the main region in a top view of the semiconductor substrate.

### BACKGROUND

### 1. TECHNICAL FIELD

The present invention relates to a semiconductor device.

### 2. RELATED ART

Conventionally, a configuration provided with a high concentration n type region below a base region is known (for example, see Patent Documents 1 to 4).

Patent Document 1: International Publication No. WO 2023/042638.

Patent Document 2: Japanese Patent Application Publication No. 2019-186311.

Patent Document 3: Japanese Patent Application Publication No. 2023-081724.

Patent Document 4: Japanese Patent Application Publication No. 2023-120081.

### BRIEF DESCRIPTION OF THE DRAWINGS

FIG. 1 is a top view illustrating an example of a semiconductor device 100.

FIG. 2A is a top view illustrating an example of the semiconductor device 100.

FIG. 2B is a top view illustrating an example of the semiconductor device 100.

FIG. 3 illustrates an example of a cross section taken along line a-a of FIG. 1.

FIG. 4 illustrates an example of a cross section taken along a line b-b of FIG. 1.

FIG. 5 illustrates an example of a relationship between a boundary contact region width-to-substrate thickness ratio Wb/T and a forward-direction voltage Vf of a diode portion.

FIG. 6 is a top view illustrating another example of the semiconductor device 100.

FIG. 7 illustrates an example of a cross section taken along a line c-c of FIG. 6.

FIG. 8 illustrates an example of a cross section taken along a line d-d of FIG. 6.

FIG. 9 is a top view illustrating another example of the semiconductor device 100.

FIG. 10 illustrates an example of a cross section taking along a line e-e of FIG. 9.

FIG. 11 illustrates an example of a cross section taken along a line f-f of FIG. 9.

FIG. 12 illustrates another example of a cross section taken along a line e-e of FIG. 9.

### DESCRIPTION OF EXEMPLARY EMBODIMENTS

The present invention will be described below through embodiments of the invention, but the following embodiments do not limit the invention according to the claims. In addition, not all combinations of features described in the embodiments are essential to a solution of the invention.

In the present specification, one side in a direction parallel to a depth direction of a semiconductor substrate is referred to as “upper” and another side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in implementation of a semiconductor device.

In the present specification, technical matters may be described by using orthogonal coordinate axes of an X axis, a Y axis, and a Z axis. The orthogonal coordinate axes merely specify relative positions of components, and do not limit a particular direction. For example, the Z axis is not limited to indicate the height direction with respect to the ground. Note that a +Z axis direction and a -Z axis direction are directions opposite to each other. When the Z axis direction is described without describing the signs, it means that the direction is parallel to the +Z axis and the -Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z-axis. In the present specification, the direction of the Z axis may be referred to as the depth direction. In addition, in the present specification, a direction parallel to the upper surface and the lower surface of the semiconductor substrate may be referred to as a horizontal direction, including an X axis direction and a Y axis direction.

A region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a p type or an n type. An n type conductivity-type may be referred to as a first conductivity type, a p type conductivity-type may be referred to as a second conductivity type, but the corresponding conductivity-types may be reversed. In the present specification, the impurity may particularly mean either a donor of the n type or an acceptor of the p type, and may be described as a dopant. In the present specification, doping means introducing the donor or the acceptor into the semiconductor substrate and turning it into a semiconductor presenting a conductivity type of the n type, or a semiconductor presenting a conductivity type of the p type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. As used herein, the net doping concentration may be simply described as the doping concentration.

A p+ type or an n+ type described in the present specification means a doping concentration higher than that of the p type or the n type, and a p- type or an n- type described herein means a doping concentration lower than that of the p type or the n type. Further, in the present specification, a description of a p++ type or an n++ type means a higher doping concentration than that of the p+ type or the n+ type. As used herein, a unit system is an SI unit system unless otherwise noted. Although a unit of a length may be expressed in cm, various calculations may be performed after conversion to meters (m).

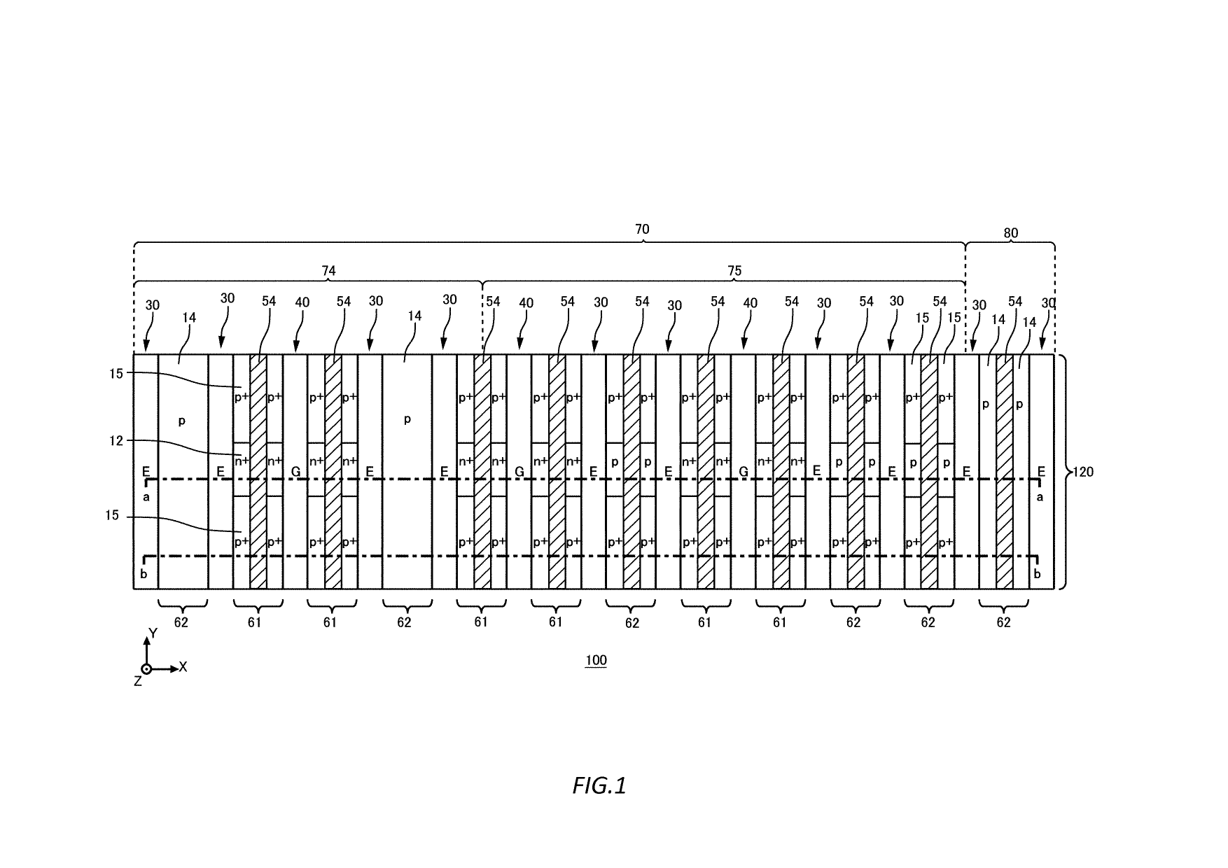

FIG. 1 is a top view illustrating an example of a semiconductor device 100. FIG. 1 illustrates a position of each member as being projected onto a front surface of a semiconductor substrate. FIG. 1 illustrates merely some members of the semiconductor device 100, and omits illustrations of some members.

The semiconductor device 100 includes the semiconductor substrate. The semiconductor substrate is provided with an active region 120. The active region 120 is a region in which a main current flows in a depth direction between the front surface and the back surface of the semiconductor substrate when the semiconductor device 100 operates. Although an emitter electrode 52 or an interlayer dielectric film 38 or the like is provided above the active region 120, these are omitted in FIG. 1.

The active region 120 is provided with a transistor portion 70 including a transistor device such as an IGBT and a diode portion 80 including a diode device such as a free wheeling diode (FWD). The semiconductor device 100 in this example is a Reverse Conducting IGBT (RC-IGBT). In the example shown in FIG. 1, the transistor portion 70 and the diode portion 80 are alternately arranged along a predetermined array direction (X axis direction) in the front surface of the semiconductor substrate.

In the present specification, a direction perpendicular to the array direction in the top view may be referred to as an extending direction (the Y axis direction). The transistor portion 70 and the diode portion 80 may each have a longitudinal length in an extending direction. That is, a length of the transistor portion 70 in the Y axis direction is greater than its width in the X axis direction. Similarly, a length of the diode portion 80 in the Y axis direction is greater than its width in the X axis direction. The extending directions of the transistor portion 70 and the diode portion 80, and a longitudinal direction of each trench portion described below may be the same.

Each of the diode portions 80 includes a cathode region of n+ type in a region in contact with the back surface of the semiconductor substrate. In the present specification, a cathode region is provided, and a region extending in the Y axis direction is referred to as a diode portion 80. The diode portion 80 includes a diode such as a free wheeling diode (FWD: Free Wheel Diode) provided to be adjacent to the transistor portion 70 at the front surface of the semiconductor substrate.

The transistor portion 70 has the collector region of the p+ type in a region in contact with the back surface of the semiconductor substrate. In the present specification, a collector region is provided, and the region extending along the Y axis direction is referred to as a transistor portion 70. The transistor portion 70 includes a transistor such as an IGBT. In the present example, the transistor portion 70 has a main region 74 and a boundary contact region 75 provided closer to the diode portion 80 than to the main region 74.

In the present example, the semiconductor device 100 includes a gate trench portion 40, a dummy trench portion 30, an emitter region 12, a base region 14 and a contact region 15 provided on a front surface of the semiconductor substrate. Each of the gate trench portion 40 and the dummy trench portion 30 is an example of the trench portion. An interlayer dielectric film 38 is provided above the front surface of the semiconductor substrate, but it is omitted in FIG. 1. In the interlayer dielectric film 38 of this example, contact holes 54 are provided passing through the interlayer dielectric film 38. In FIG. 1, contact holes 54 are shaded with diagonal hatching. In the present example, the contact holes 54 are provided extending in the Y axis direction along the adjacent trench portion.

Each of the transistor portion 70 and the diode portion 80 has a plurality of trench portions arrayed in the trench array direction (X axis direction). In the transistor portion 70 of the present example, one gate trench portion 40 and two dummy trench portions 30 are alternately provided along the X axis direction. The diode portion 80 of this example is provided with a plurality of dummy trench portions 30 along the X axis direction. In FIG. 1 and the following drawings, the gate trench portion 40 is labeled with the symbol G, and the dummy trench portion 30 is labeled with the symbol E.

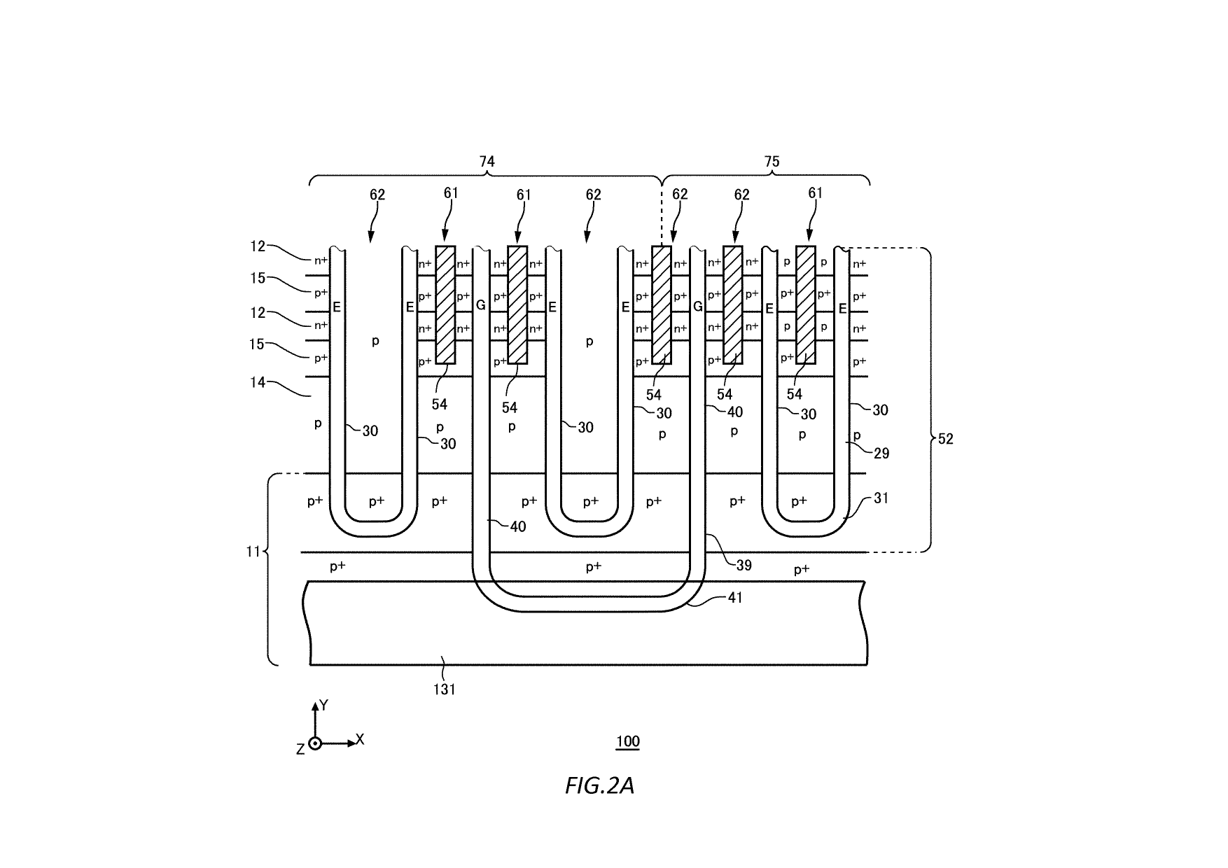

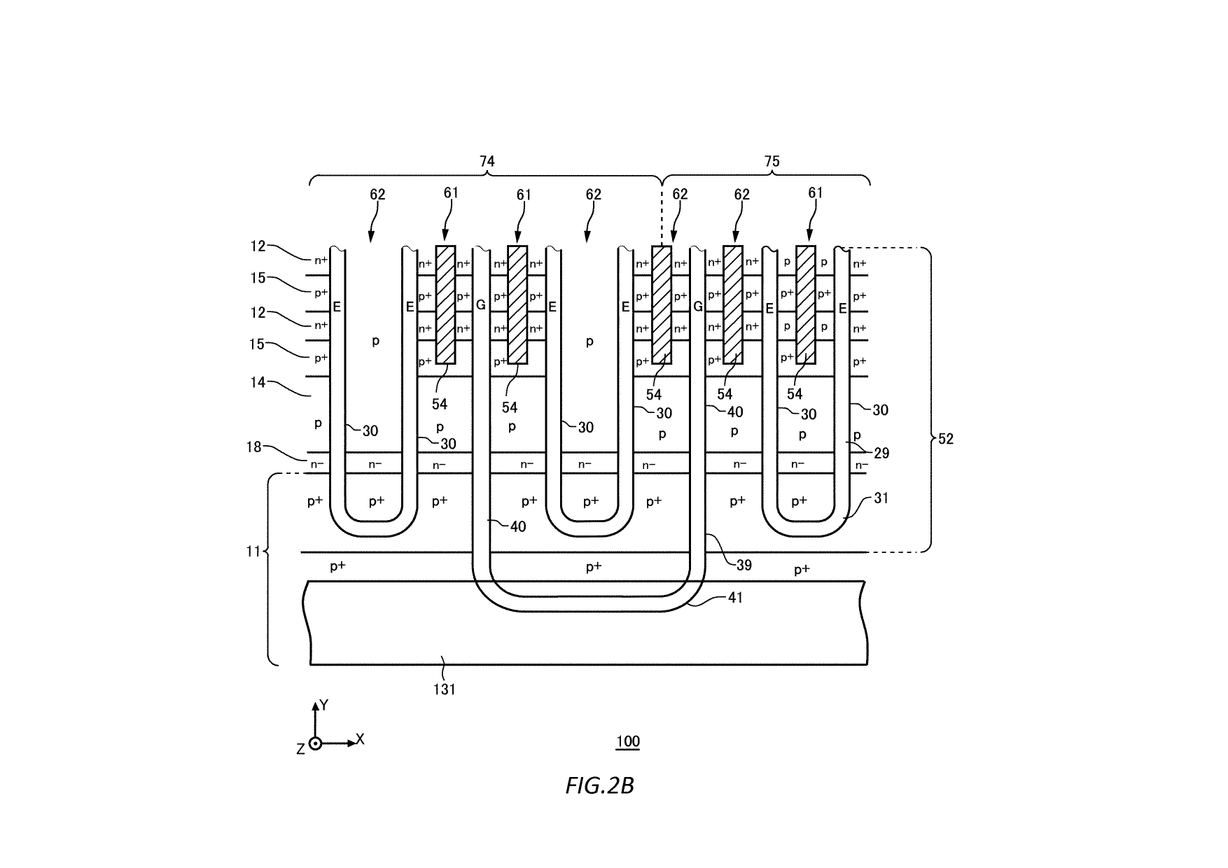

In the X axis direction, a mesa portion is provided between the adjacent trench portions. The mesa portion refers to a region sandwiched between the trench portions inside the semiconductor substrate. The trench portion herein refers to a linear portion (the linear portion 29 or the linear portion 39 in FIG. 2A and FIG. 2B) of the trench portion described below. As an example, a depth position of the mesa portion is from the front surface of the semiconductor substrate to a lower end of the trench portion. The mesa portion in the present example is provided to be sandwiched between the adjacent trench portions in the X axis direction, and to extend in the Y axis direction along the trench on the front surface of the semiconductor substrate.

In the present example, the mesa portion includes a first mesa portion 61 and a second mesa portion 62. The first mesa portion 61 in the present example is a mesa portion sandwiched between the gate trench portion 40 and the dummy trench portion 30 adjacent to each other, and the second mesa portion 62 in the present example is a mesa portion sandwiched between two adjacent dummy trench portions 30. That is, the mesa portion of the transistor portion 70 in the present example is any of the first mesa portion 61 or the second mesa portion 62, and the mesa portion of the diode portion 80 in the present example is the second mesa portion 62.

In the present example, the first mesa portion 61 has an n+ type emitter region 12 and a p+ type contact region 15 exposed on the front surface of the semiconductor substrate. The emitter region 12 is provided in contact with the gate trench portion 40. In the present example, each of the emitter region 12 and the contact region 15 in the first mesa portion 61 is provided from one trench portion to the other trench portion in the X axis direction. In the first mesa portion 61 in the present example, the emitter region 12 and the contact region 15 are alternately arranged along the Y axis direction.

In another example, the emitter region 12 and the contact region 15 of the first mesa portion 61 may be provided in a stripe-like pattern along the Y axis direction. For example, the emitter region 12 is provided in a region in contact with the trench portion, and the contact region 15 is provided in a region sandwiched between the emitter regions 12.

The contact hole 54 is provided above each first mesa portion 61. In the present example, the contact holes 54 are provided in each region of the contact region 15, the emitter region 12 and the contact region 15. The contact holes 54 may be arranged in the center of the first mesa portion 61 in the X axis direction.

In the main region 74 of the present example, the second mesa portion 62 has a base region 14 exposed on the front surface of the semiconductor substrate. In the present example, no emitter region 12 is provided in the second mesa portions 62. In the present example, the contact holes 54 are not provided in the second mesa portion 62 of the main region 74.

On the other hand, in the boundary contact region 75 of the present example, the second mesa portion 62 has a contact region 15 exposed on the front surface of the semiconductor substrate. In each second mesa portion 62 of the boundary contact region 75, a plurality of contact regions 15 may be discretely provided along the Y axis direction, and the base region 14 may be provided to be exposed on the front surface of the semiconductor substrate between the adjacent contact regions 15. In the present example, in the second mesa portion 62 of the boundary contact region 75, each of the base region 14 and the contact region 15 is provided from one trench portion to the other trench portion in the X axis direction. In the present example, in the second mesa portion 62 of the boundary contact region 75, the base regions 14 and the contact regions 15 are alternately arranged along the Y axis direction. However, in the second mesa portion 62 closest to the diode portion 80 side, the base region 14 may not be exposed on the front surface of the semiconductor substrate, and the contact region 15 may be provided to extend along the Y axis direction.

In the present example, the contact holes 54 are provided above the second mesa portion 62 of the boundary contact region 75. That is, in the main region 74 of the present example, in contrast to the fact that the contact holes 54 are provided only above each first mesa portion 61, but not provided above the second mesa portion 62, in the boundary contact region 75 of the present example, the contact holes 54 are provided above any of the first mesa portion 61 or the second mesa portion 62. Therefore, the area proportion of the contact holes 54 in the boundary contact region 75 of the present example is greater than that of the main region 74 in a top view of the semiconductor substrate.

In another example, instead of providing contact holes 54 above the second mesa portion 62 of the boundary contact region 75, by having a width in the X axis direction of the contact holes 54 provided above the first mesa portion 61 of the boundary contact region 75 greater than a width in the X axis direction of the contact holes 54 provided above the first mesa portion 61 of the main region 74, the area proportion of the contact holes 54 in the boundary contact region 75 may be greater than the area proportion in the main region 74.

The second mesa portion 62 of the diode portion 80 is not provided with the emitter region 12. The base region 14 may be provided on an upper surface of the second mesa portion 62 of the diode portion 80. The base region 14 may be arranged across the entire second mesa portion 62 of the diode portion 80. Contact holes 54 are provided in the second mesa portion 62 of the diode portion 80.

In the present example, a width in the X axis direction of each mesa portion is the same. That is, in the present example, the width in the X axis direction of the mesa portion (the first mesa portion 61 or the second mesa portion 62) of the main region 74 is the same as the width in the X axis direction of the mesa portion (the first mesa portion 61 or the second mesa portion 62) of the boundary contact region 75. Also, the width in the X axis direction of the mesa portion (the first mesa portion 61 or the second mesa portion 62) of the transistor portion 70 is the same as the width in the X axis of the mesa portion (the second mesa portion 62) of the diode portion 80.

FIG. 2A and FIG. 2B are top views illustrating an example of the semiconductor device 100. FIG. 2A and FIG. 2B illustrate a region closer to an end portion side of the Y axis direction than FIG. 1, in particular, a region close to the boundary between the main region 74 and the boundary contact region 75 of the transistor portion 70. In the present example, although it is shown that the boundary between the main region 74 and the boundary contact region 75 is arranged in the second mesa portion 62, it is not limited thereto. The width in the X axis direction of the boundary contact region 75 may fall in a numerical range described below. FIG. 2B is different from FIG. 2A in that the front surface of the semiconductor substrate is exposed between the base region 14 of each mesa portion and the well region 11, and each mesa portion is separated from the well region 11 by the drift region 18 in the end portion in the Y axis direction.

In the present example, the semiconductor device 100 includes an emitter electrode 52 and a gate runner 131 provided above the front surface of the semiconductor substrate. The emitter electrode 52 and the gate runner 131 are provided to be separated from each other. Although an interlayer dielectric film is provided between a set of the emitter electrode 52 and the gate runner 131 and the front surface of the semiconductor substrate, it is omitted in FIG. 2A and FIG. 2B. FIG. 2A and FIG. 2B illustrate a range of areas where the emitter electrode 52 is provided. In a top view of the semiconductor substrate, the range of area where the emitter electrode 52 is provided may match the range of area of the active region 120.

The gate runner 131 is connected to the gate trench portion 40 through the contact hole provided in the interlayer dielectric film. The gate runner 131 may be connected to a gate conductive portion of the gate trench portion 40 at an edge portion 41 of the gate trench portion 40 in the Y axis direction. The gate runner 131 is not connected to the dummy conductive portion in the dummy trench portion 30.

In the present example, the semiconductor substrate has a well region 11 provided overlapping the gate runner 131. In the present example, the well region 11 is provided to extend with a predetermined width even to a range not overlapping the gate runner 131. The well region 11 in this example is provided away from an end of the contact hole 54 in the Y axis direction toward the gate runner 131 side. The well region 11 is a region of a second conductivity type having a higher doping concentration than the base region 14. In the present example, the base region 14 is of a p type, and the well region 11 is of a p+ type.

A diffusion depth of the well region 11 may be deeper than the depth of the gate trench portion 40 and the dummy trench portion 30. End portions of the gate trench portion 40 and the dummy trench portion 30 in the Y axis direction are provided in the well region 11 in the top view. That is, the bottom portion in a depth direction of each trench portion is covered with the well region 11 at the end portion in the Y axis direction of each trench portion. With this configuration, the electric field strength on the bottom portion of each trench portion can be reduced.

The gate trench portion 40 in the present example may have two linear portions 39 extending along the Y axis direction, and an edge portion 41 that connects the two linear portions 39. Preferably, at least a part of the edge portion 41 is provided in a curved shape in a top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided or a plurality of dummy trench portions 30 may be provided. In the transistor portion 70 of the present example, two dummy trench portions 30 are provided between each two linear portions 39. The dummy trench portion 30 may have a linear shape extending in the Y axis direction, or may have linear portions 29 and an edge portion 31 similar to the gate trench portion 40. Although the semiconductor device 100 shown in FIG. 2A and FIG. 2B only has the dummy trench portion 30 with the edge portions 31, it may have both a linear shaped dummy trench portion 30 without edge portions 31 and a dummy trench portion 30 with edge portions 31.

The base region 14 is provided in each mesa portion. In FIG. 2A and FIG. 2B, although the base region 14 is shown to be arranged in one end portion in the Y axis direction of each mesa portion, the base region 14 is also arranged in the other end portion of each mesa portion. In the first mesa portion 61 of the present example, the emitter region 12 and the contact region 15 may be alternately provided in a region sandwiched by the base regions 14 in a top view. The emitter region 12 and the contact region 15 may be provided between the base region 14 and the front surface of the semiconductor substrate in the depth direction. In the second mesa portion 62 of the present example, the base region 14 may be provided to extend in the Y axis direction along the dummy trench portion 30.

In the present example, the contact holes 54 are arranged in a region sandwiched by the base regions 14. The contact holes 54 of the present example are provided above respective regions of the contact region 15, the base region 14, and the emitter region 12. The contact holes 54 are not provided in the base region 14 or the well region 11.

In the present example, the semiconductor substrate has an n- type drift region 18. In the present example, the drift region 18 has the base region 14 of each mesa portion and the well region 11 in contact in the top view of the semiconductor substrate, as shown in FIG. 2A. Also, as shown in FIG. 2B, the front surface of the semiconductor substrate may be exposed between the base region 14 of each mesa portion and the well region 11, and each mesa portion may be separated from the well region 11 by the drift region 18 in the end portion in the Y axis direction. In another example, the drift region 18 may be exposed on the front surface of the semiconductor substrate in the second mesa portion 62, and not exposed on the front surface of the semiconductor substrate in the first mesa portion 61.

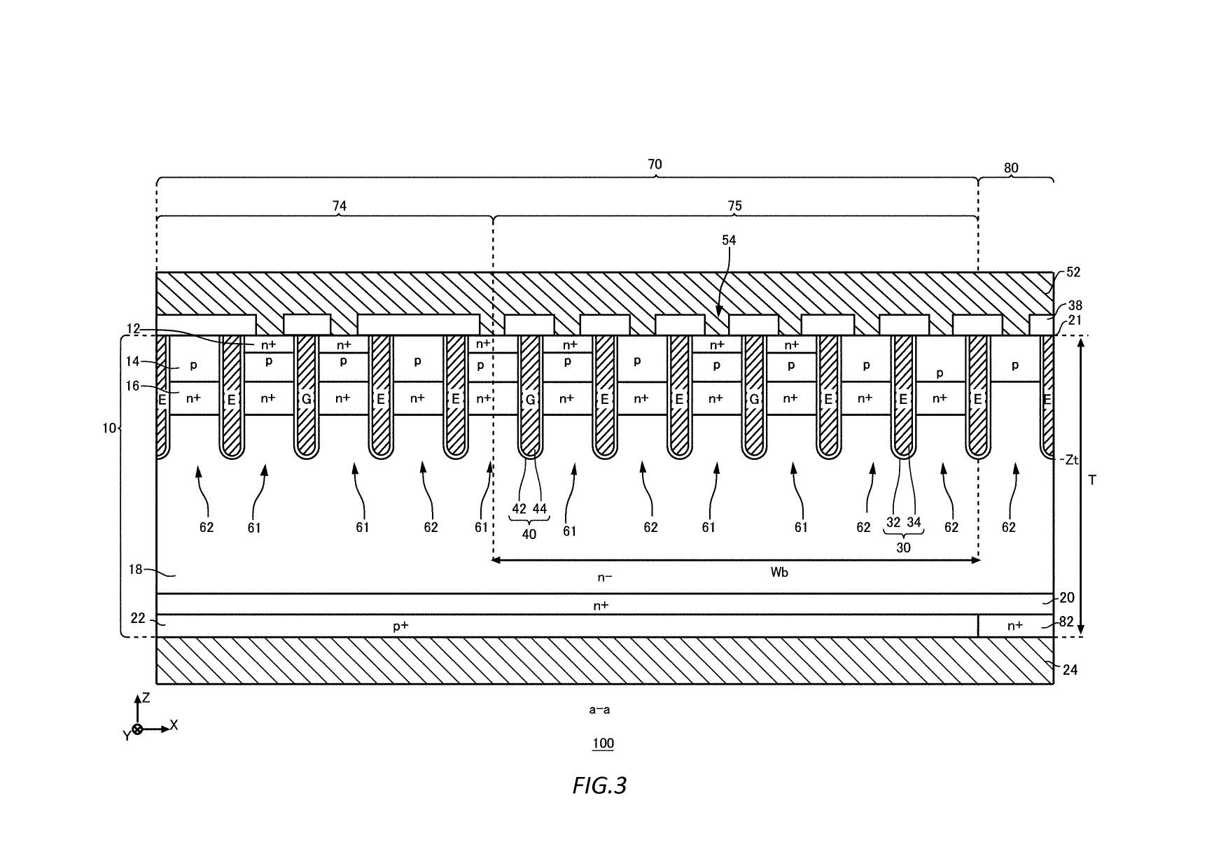

FIG. 3 illustrates an example of a cross section taken along line a-a of FIG. 1. The cross section a-a is an XZ plane passing through the emitter region 12. The semiconductor device 100 includes a semiconductor substrate 10, an interlayer dielectric film 38 and an emitter electrode 52. The semiconductor substrate 10 is a substrate which is formed of a semiconductor material. As an example, the semiconductor substrate 10 is a silicon substrate. The semiconductor substrate 10 may be a silicon carbide substrate, or a gallium nitride substrate, or a substrate made of another semiconductor material. The semiconductor substrate 10 has a front surface 21 and a back surface 23. The semiconductor device 100 includes a semiconductor substrate 10, an interlayer dielectric film 38 and an emitter electrode 52.

The interlayer dielectric film 38 is provided above the front surface 21 of the semiconductor substrate 10. The interlayer dielectric film 38 is a film including at least one layer of a dielectric film such as silicate glass to which impurities such as boron or phosphorous are added, a thermal oxide film, or other dielectric films. The contact holes 54 are formed in the interlayer dielectric film 38 of the present example. The contact holes 54 are through holes provided to pass through the interlayer dielectric film 38.

The emitter electrode 52 is provided above a front surface 21 of the semiconductor substrate 10. In the present example, the emitter electrode 52 is provided above the interlayer dielectric film 38. The emitter electrode 52 is connected to the front surface 21 of the semiconductor substrate 10 via the contact holes 54. The emitter electrode 52 may be an alloy containing alluminium, aluminum-silicon alloy as an example. The emitter electrode 52 may be a multi-layered structure consisting of a barrier metal, such as titanium, titanium nitride or the like, and an aluminum-silicon alloy.

Contact plug portions may be provided to connect the emitter electrode 52 and the semiconductor substrate 10 inside the contact holes 54. The contact plug portion may have a plug formed of tungsten or the like, and a barrier metal, including titanium, provided in a portion in contact with the semiconductor substrate 10. The barrier metal may have a titanium nitride layer, or may have a stacking structure of a titanium nitride layer and a titanium layer.

An n- type drift region 18 is provided inside the semiconductor substrate 10. In the transistor portion 70, a p+ type collector region 22 is provided on the back surface 23 of the semiconductor substrate 10. In the diode portion 80, an n+ type cathode region 82 is provided on the back surface 23 of the semiconductor substrate 10. The collector electrode 24 is provided in contact with the collector region 22 and the cathode region 82. An n+ type field stop layer (FS layer) with an impurity concentration higher than that of the drift region 18 may be provided between the drift region 18 and a set of the collector region 22 and the cathode region 82. The drift region 18 may be a region with a certain doping concentration.

The semiconductor substrate 10 has a plurality of trench portions provided toward the inside from the front surface 21 of the semiconductor substrate 10. The trench portion may reach the drift region 18 inside the semiconductor substrate 10. The plurality of trench portions may include one or more gate trench portions 40, and may include one or more dummy trench portions 30. The gate trench portion 40 is a trench portion with a gate voltage applied thereon. The dummy trench portion 30 is connected to the emitter electrode 52 in another cross section.

In the present example, the trench portion includes a plurality of gate trench portions 40 and a plurality of dummy trench portions 30. Each trench portion extends in the Y axis direction. Also, the plurality of trench portions are arrayed in the X axis direction. In FIG. 2A and FIG. 2B, one gate trench portion 40 and two dummy trench portions 30 are alternately arrayed.

The gate trench portion 40 has a gate trench, a gate dielectric film 42, and the gate conductive portion 44 that are provided at the front surface 21 of the semiconductor substrate 10. The gate dielectric film 42 is provided covering an inner wall of the gate trench. The gate dielectric film 42 may be formed by oxidizing or nitriding a semiconductor on the inner wall of the gate trench. The gate conductive portion 44 is provided on an inner side further than the gate dielectric film 42 in the gate trench. That is, the gate dielectric film 42 insulates the gate conductive portion 44 from the semiconductor substrate 10. The gate conductive portion 44 is formed of a conductive material such as polysilicon.

The gate trench portion 40 may be provided to be longer than the base region 14 in the depth direction. The gate conductive portion 44 may be provided longer than the base region 14 in the depth direction. The gate trench portion 40 in the cross section is covered with the interlayer dielectric film 38 on the front surface 21 of the semiconductor substrate 10. When a predetermined gate voltage is applied to the gate conductive portion 44, a channel is formed by an electron inversion layer in a surface layer of the base region 14 at a boundary in contact with the gate trench portion 40. In this manner, a main current flows between the emitter electrode 52 and the collector electrode 24.

The dummy trench portions 30 may have a similar structure to the gate trench portions 40 in the cross section. That is, the dummy trench portion 30 has a dummy trench, a dummy dielectric film 32 and a dummy conductive portion 34 provided on the front surface 21 of the semiconductor substrate 10. The dummy conductive portion 34 is electrically connected to the emitter electrode 52 in another cross section. The dummy dielectric film 32 is provided to cover an inner wall of the dummy trench. The dummy conductive portion 34 is provided in the dummy trench, and is provided on an inner side further than the dummy dielectric film 32. The dummy dielectric film 32 insulates the dummy conductive portion 34 from the semiconductor substrate 10. The dummy conductive portion 34 may be formed of a same material as the gate conductive portion 44. For example, the dummy conductive portion 34 is formed of a conductive material such as polysilicon. The dummy conductive portion 34 may have the same length as that of the gate conductive portion 44 in the depth direction.

The gate trench portion 40 and the dummy trench portion 30 of the present example are covered with the interlayer dielectric film 38 at the front surface 21 of the semiconductor substrate 10. It should be noted that bottom portions of the dummy trench portion 30 and the gate trench portion 40 may have curved surfaces which are convex downward (curved shapes in the cross sections). The depth position of the lower end of the gate trench portion 40 may be the same as the depth position of the lower end of the dummy trench portion 30.

The first mesa portion 61 or the second mesa portion 62 is provided between adjacent trench portions in the X axis direction. The upper end of these mesa portions is the front surface 21 of the semiconductor substrate 10, and the depth position of the lower end may be the same as the depth position of the lower end of the trench portion.

In the present example, the first mesa portion 61 is in contact with the gate trench portion 40. In the present example, the first mesa portion 61 has an emitter region 12 and a base region 14 provided to be in contact with the gate trench portion 40. The emitter region 12 and the base region 14 are provided in order from the front surface 21 side of the semiconductor substrate 10.

The emitter region 12 has a higher doping concentration than the drift region 18. The emitter region 12 and the base region 14 may be in contact with each other in the depth direction (Z axis direction) of the semiconductor substrate 10. The emitter region 12 and the base region 14 may be in contact with two trench portions sandwiching the first mesa portion 61.

In the present example, the first mesa portion 61 is connected to the emitter electrode 52 through the contact holes 54. The emitter region 12 of the first mesa portion 61 is in contact with the emitter electrode 52 through the contact holes 54.

An n- type drift region 18 is provided inside the semiconductor substrate 10. The drift region 18 may be a region where doping has not been performed on the semiconductor substrate 10. The base region 14 is provided above the drift region 18 in the semiconductor substrate 10.

An n+ type accumulation region 16 provided in contact with the gate trench portion 40 is arranged between the base region 14 and the drift region 18. The accumulation region 16 has a higher doping concentration than the drift region 18. By providing the high concentration accumulation region 16 between the drift region 18 and the base region 14, enhancing the carrier injection enhancement effect (IE effect) can reduce the collector-emitter saturation voltage Vce (sat). The accumulation region 16 may contact two trench portions sandwiching the mesa portion.

In the present example, the accumulation region 16 is in contact with the drift region 18. The accumulation region 16 and the base region 14 may be in contact with each other in the Z axis direction, or may be away from each other. Although, in the present example, the accumulation region 16 is provided only in the mesa portion (the first mesa portion 61 and the second mesa portion 62) of the transistor portion 70, in another example, the accumulation region 16 may also be provided in the diode portion 80.

The second mesa portion 62 may have a structure similar to that of the first mesa portion 61. Note that an emitter region 12 may not be provided in the second mesa portion 62. In the second mesa portion 62, the base region 14 may be provided instead of the emitter region 12. In the second mesa portion 62 of the present example, the base region 14 that is exposed on the front surface 21 of the semiconductor substrate 10 is provided.

In the present example, the second mesa portion 62 provided in the main region 74 does not have contact holes 54 provided therein. That is, the second mesa portion 62 provided in the main region 74 of the present example is a floating mesa portion covered by the interlayer dielectric film 38. The floating mesa portion refers to a mesa portion to which the emitter electrode 52 is not connected by the contact holes 54. The floating mesa portion of the present example may be separated from the well region 11 by the drift region 18 in the end portion in the Y axis direction as shown in FIG. 2B. In the present example, the second mesa portion 62 provided in the main region 74 is not connected to the emitter electrode 52 by the contact holes 54. In this manner, during operation of the transistor portion 70, suppressing the extraction of holes accumulated below the second mesa portion 62 of the main region 74 can promote the IE effect.

On the other hand, the second mesa portion 62 provided in the boundary contact region 75 of the present example is connected to the emitter electrode 52 by the contact holes 54. That is, the second mesa portion 62 provided in the boundary contact region 75 of the present example has a larger contact area with the emitter electrode 52 than the second mesa portion 62 provided in the main region 74 of the present example.

The second mesa portion 62 of the diode portion 80 has a structure similar to that of the second mesa portion 62 provided in the main region 74 of the transistor portion 70. Note that the base region 14 of the second mesa portion 62 of the diode portion 80 is connected to the emitter electrode 52 by the contact holes 54.

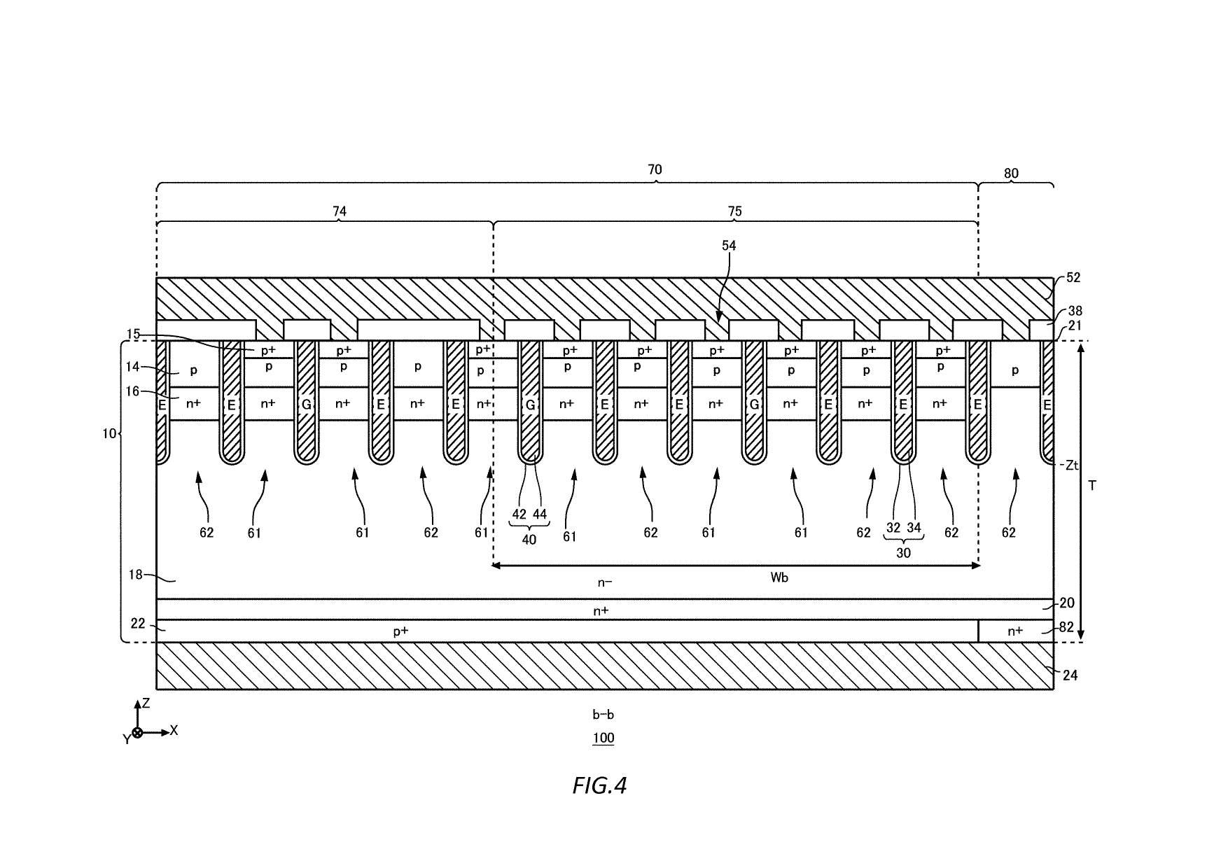

FIG. 4 illustrates one example of a cross section taken along a line b-b in FIG. 1. The cross section b-b is an XZ plane passing through the contact region 15. The second mesa portion 62 provided in the main region 74 of the present example, the base region 14 is provided exposed on the front surface 21 of the semiconductor substrate 10. In the second mesa portion 62 provided in the boundary contact region 75 of the present example, the contact region 15 is provided exposed on the front surface 21 of the semiconductor substrate 10. The contact region 15 of the boundary contact region 75 of the present example is connected to the emitter electrode 52 by the contact holes 54.

In this manner, in the XZ plane, the area proportion of the contact region 15 in the boundary contact region 75 is greater than the area proportion of the contact region 15 in the main region 74 in the present example. Therefore, the integrated concentration of the p type dopant in the boundary contact region 75 of the present example is greater than the integrated concentration of the p type dopant in the main region 74.

Additionally, as described above, in the boundary contact region 75 of the present example, since the contact holes 54 are provided throughout the mesa portion, the area proportion of the contact holes 54 in the boundary contact region 75 is greater than the area proportion of the contact holes 54 in the main region 74 in a top view of the semiconductor substrate 10. Therefore, during operation of the diode portion 80, promoting hole implantation from the boundary contact region 75 close to the diode portion 80 can reduce the forward-direction voltage Vf of the diode portion 80.

In the present example, the width Wb in the X axis direction of the boundary contact region 75 is 10% or more of the thickness T of the semiconductor substrate 10, and equal to or less than the thickness T of the semiconductor substrate 10. Also, the width Wb in the X axis direction of the boundary contact region 75 of the present example is 6 μm or more and 18.5 μm or less.

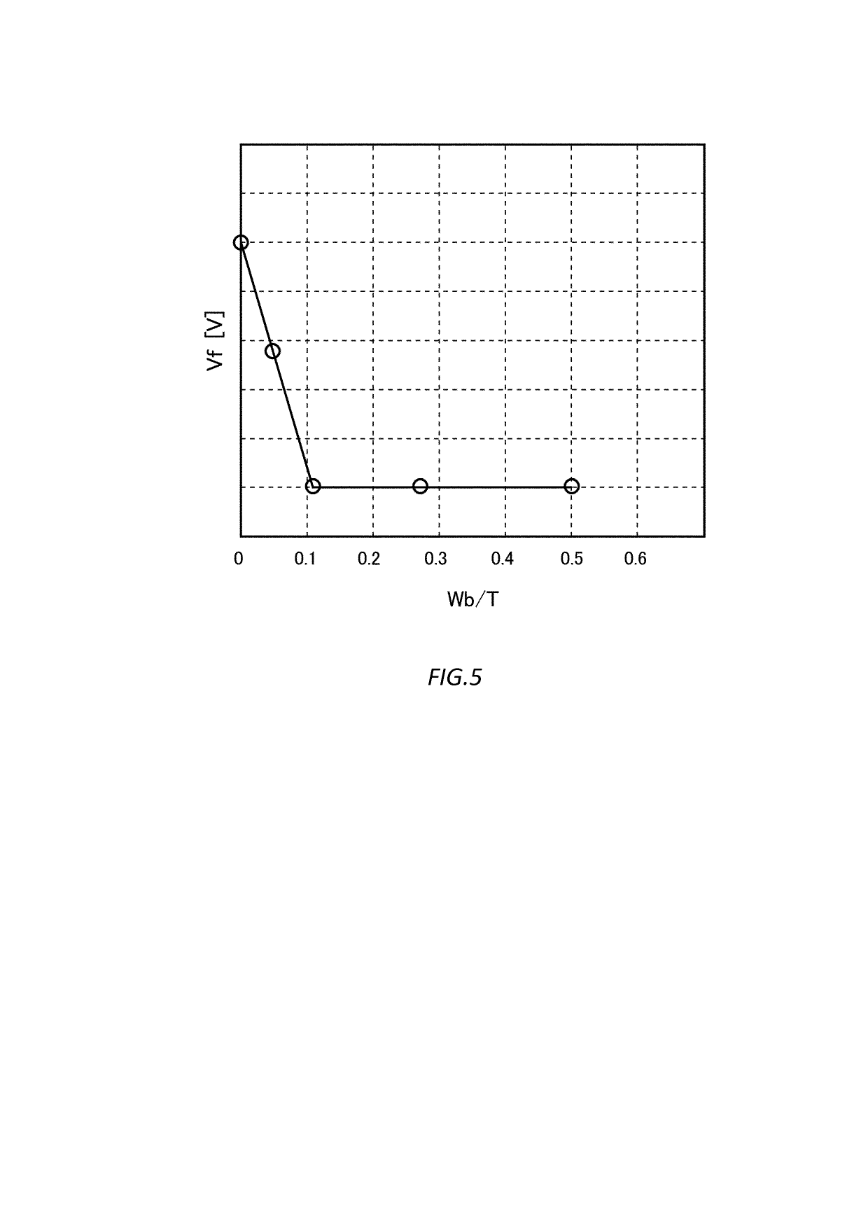

FIG. 5 illustrates an example of a relationship between the boundary contact region width-to-substrate thickness ratio Wb/T and the forward-direction voltage Vf of the diode portion. The horizontal axis indicates Wb/T, which is a ratio between the width Wb in the X axis direction of the boundary contact region 75 and the thickness of the semiconductor substrate 10, and the vertical axis indicates the forward-direction voltage Vf of the diode portion 80.

First, when the boundary contact region 75 is not provided, that is, when Wb/T is 0, all the second mesa portions 62 of the transistor portion 70 are floating mesa portions. In this case, during operation of the transistor portion 70, the extraction of holes accumulated below the second mesa portion 62 is suppressed. Consequently, while Vce(sat) is reduced due to the enhanced IE effect, the implantation of holes from the transistor portion 70 into the diode portion 80 during its operation is also suppressed, causing Vf to increase.

Then, when the boundary contact region 75 is provided close to the diode portion 80, during operation of the diode portion 80, implantation of holes from the boundary contact region 75 is promoted, enabling a reduction in Vf. As Wb/T increases from 0 to 1.0, Vf decreases. When Wb/T exceeds 0.1, Vf reaches its lower limit and indicates a constant. For example, when the thickness of the semiconductor substrate 10 is 110 μm, the width Wb of the boundary contact region 75 in the X axis direction is 12 μm, and Vf indicates the lower limit value.

In this manner, by providing the boundary contact region 75, during operation of the transistor portion 70, the extraction of holes accumulated below the second mesa portion 62 of the main region 74 is suppressed to promote the IE effect. Meanwhile, during operation of the diode portion 80, the implantation of holes from the boundary contact region 75 close to the diode portion 80 is promoted. This enables both a reduction in Vce (sat) through promoted IE effect and a reduction in Vf through promoted hole implantation.

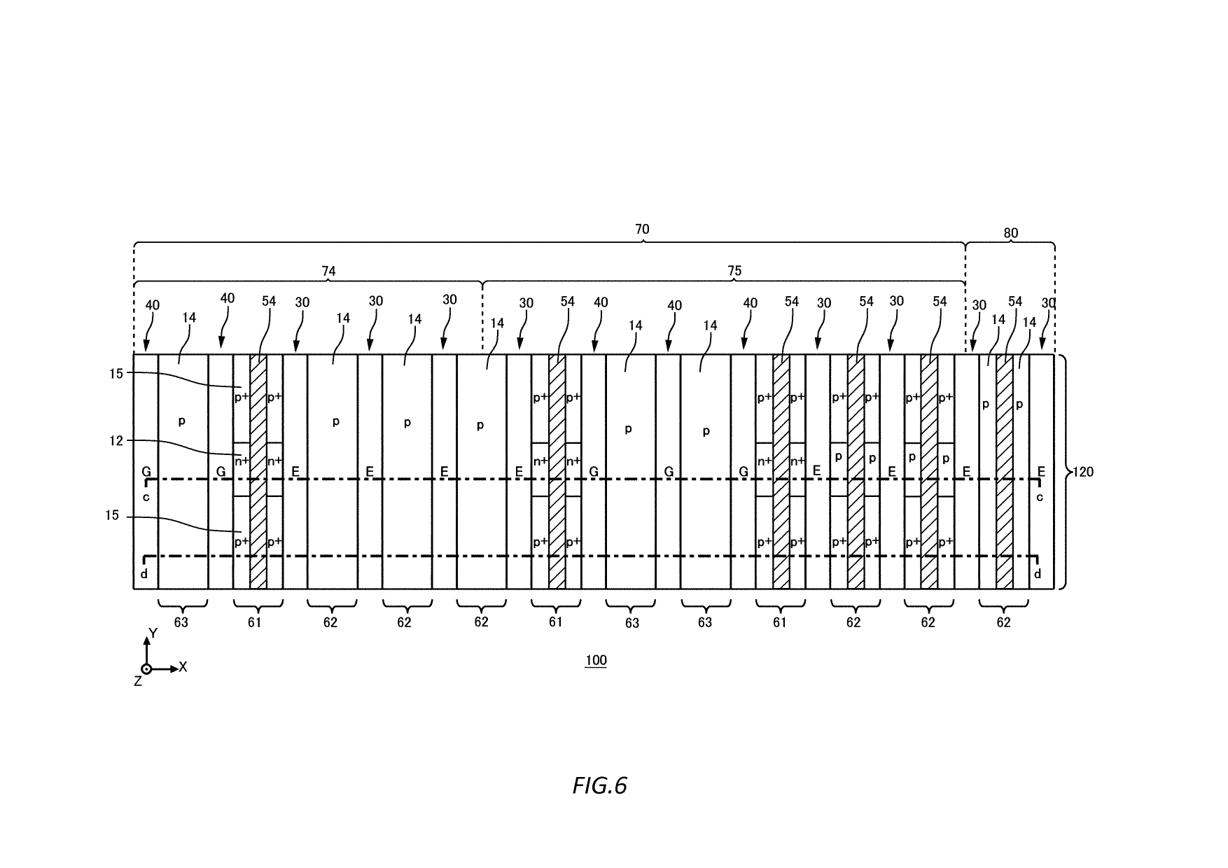

FIG. 6 is a top view illustrating another example of the semiconductor device 100. The transistor portion 70 of the present example is different from the example in FIG. 1 in that it is provided with three gate trench portions 40 and four dummy trench portions 30 that are arranged alternately along the X axis direction. Herein, the same symbols are assigned to the same elements as in the example in FIG. 1, and explanations are omitted.

In the present example, the mesa portion includes a third mesa portion 63 in addition to the first mesa portion 61 and the second mesa portion 62. In the present example, the third mesa portion 63 is a mesa portion sandwiched by two adjacent gate trench portions 40. That is, in the present example, the mesa portion of the transistor portion 70 is any of the first mesa portion 61, the second mesa portion 62 or the third mesa portion 63, and the mesa portion of the diode portion 80 of the present example is the second mesa portion 62. In the present example, the width in the X axis direction of each mesa portion is the same.

In the present example, similar to FIG. 2A, the mesa portion may be in contact with the base region 14 and the well region 11 in the end portion in the Y axis direction. Also, similar to FIG. 2B, in the end portion in the Y axis direction, the base region 14 may be separated from the well region 11 by the drift region 18. In the present example, similar to FIG. 2A and FIG. 2B, the gate trench portion 40 may have an edge portion 41 that connects the linear portion 39 and two linear portions 39. In the present example, similar to FIG. 2A and FIG. 2B, the dummy trench portion 30 may have an edge portion 31 that connects the linear portion 29 and two linear portions 29.

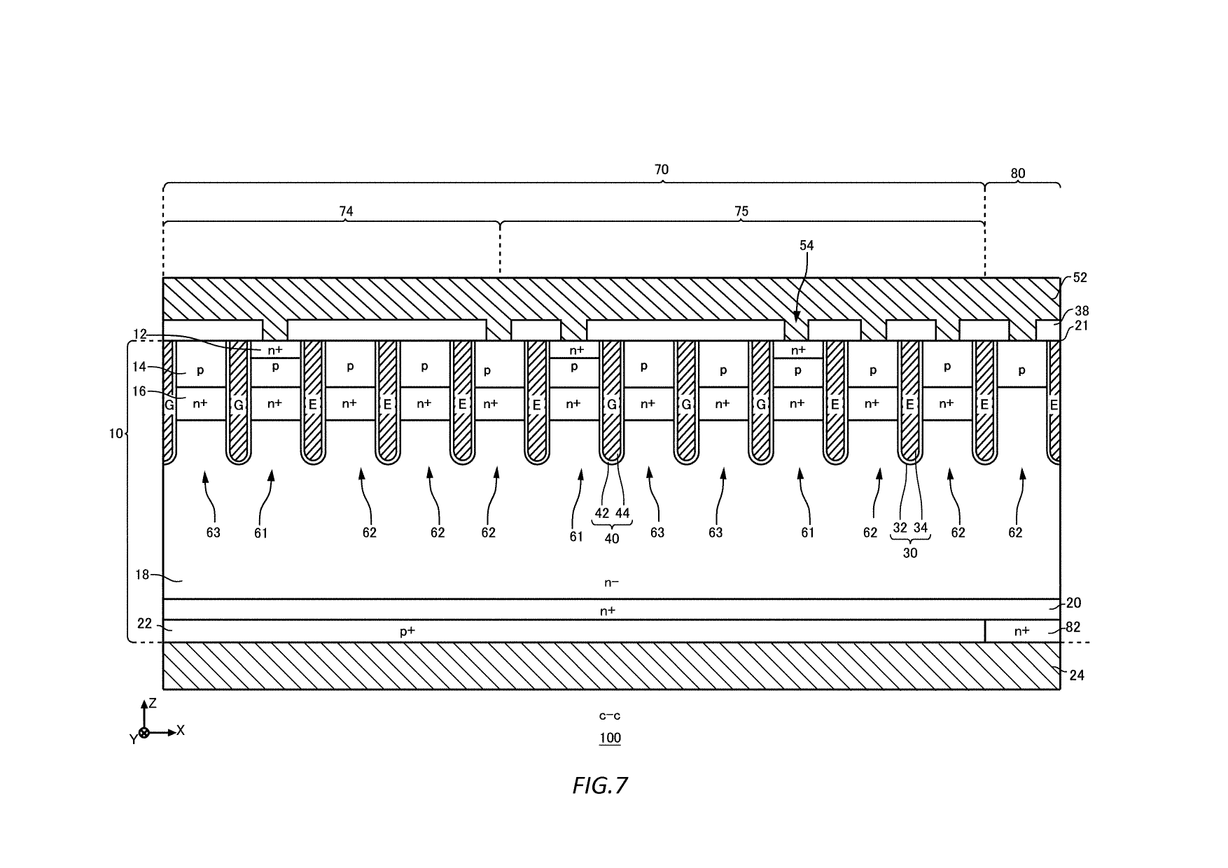

FIG. 7 illustrates an example of the cross section along the line c-c of FIG. 6. The cross section c-c is an XZ plane passing through the emitter region 12. In the present example, the interlayer dielectric film 38 has contact holes 54. In the present example, the contact holes 54 are provided only in the first mesa portion 61 in the main region 74 of the transistor portion 70. In the present example, the contact holes 54 are also provided above the second mesa portion 62 in addition to the first mesa portion 61 in the boundary contact region 75 of the transistor portion 70. In the diode portion 80, the contact holes 54 of the present example are provided above all the mesa portion.

In the third mesa portion 63 of the present example, the base region 14 is exposed on the front surface 21 of the semiconductor substrate 10. In the third mesa portion 63 of the present example, the contact holes 54 are not provided. That is, the third mesa portion 63 of the present example is a floating mesa portion covered by the interlayer dielectric film 38 in any of the main region 74 or the boundary contact region 75, similar to the second mesa portion 62 provided in the main region 74. The emitter region 12 may not be provided in the third mesa portion 63.

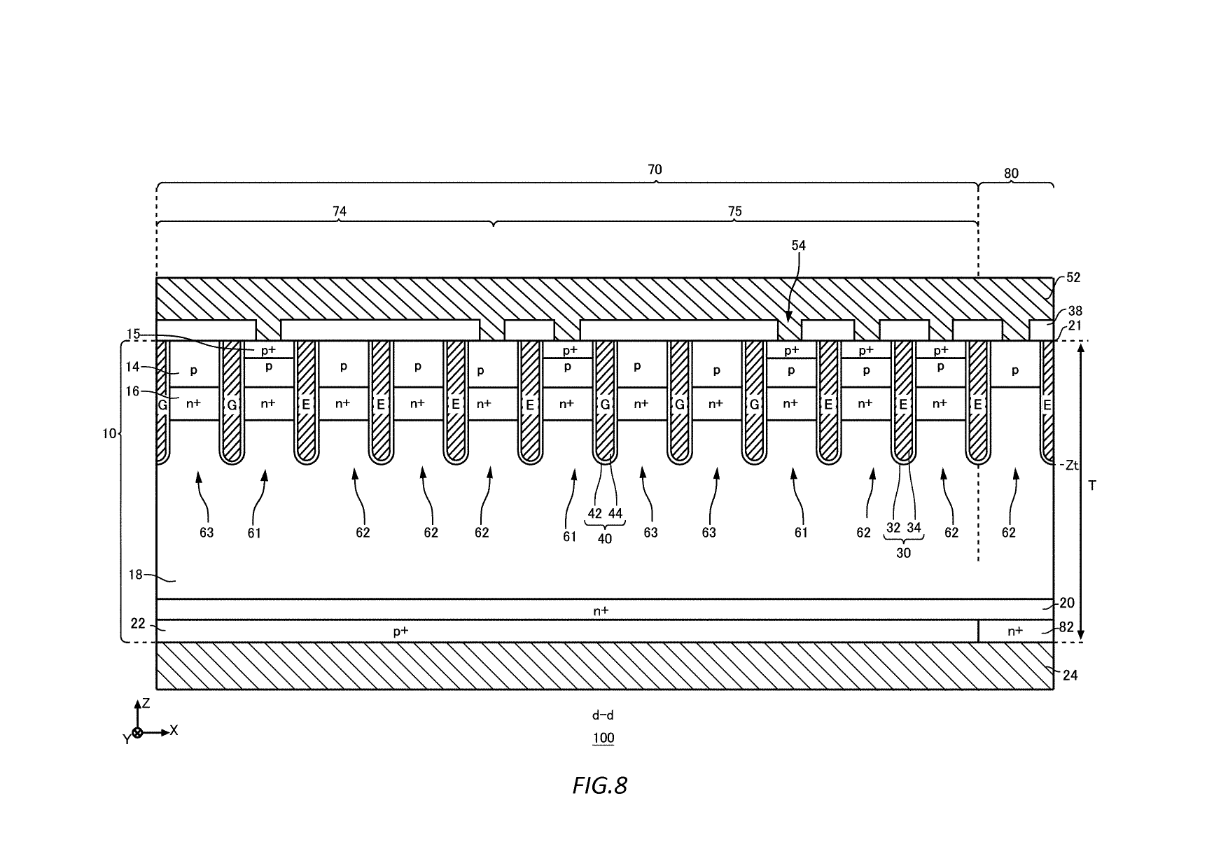

FIG. 8 illustrates an example of a cross section in a line d-d of FIG. 6. The cross section d-d is an XZ plane passing through the contact region 15. Also in the cross section d-d, in the third mesa portion 63 of the present example, the base region 14 is exposed on the front surface 21 of the semiconductor substrate 10. The contact region 15 may not be provided in the third mesa portion 63.

The third mesa portion 63, which is the floating mesa portion, is provided in the boundary contact region 75 of the present example. This can promote the accumulation of holes and enhance the IE effect. On the other hand, when compared to the case of providing the contact holes 54 in the third mesa portion 63 of the boundary contact region 75, the amount of hole implantation decreases during operation of the diode portion 80.

However, since the second mesa portion 62 is sandwiched between the adjacent dummy trench portions 30, even if electron extraction is promoted via the contact holes 54, it does not affect implantation. Therefore, in the boundary contact region 75 of the present example, by connecting the second mesa portion 62 to the emitter electrode 52, and regading the third mesa portion 63 as a floating mesa portion, both transistor characteristics and diode characteristics are ensured.

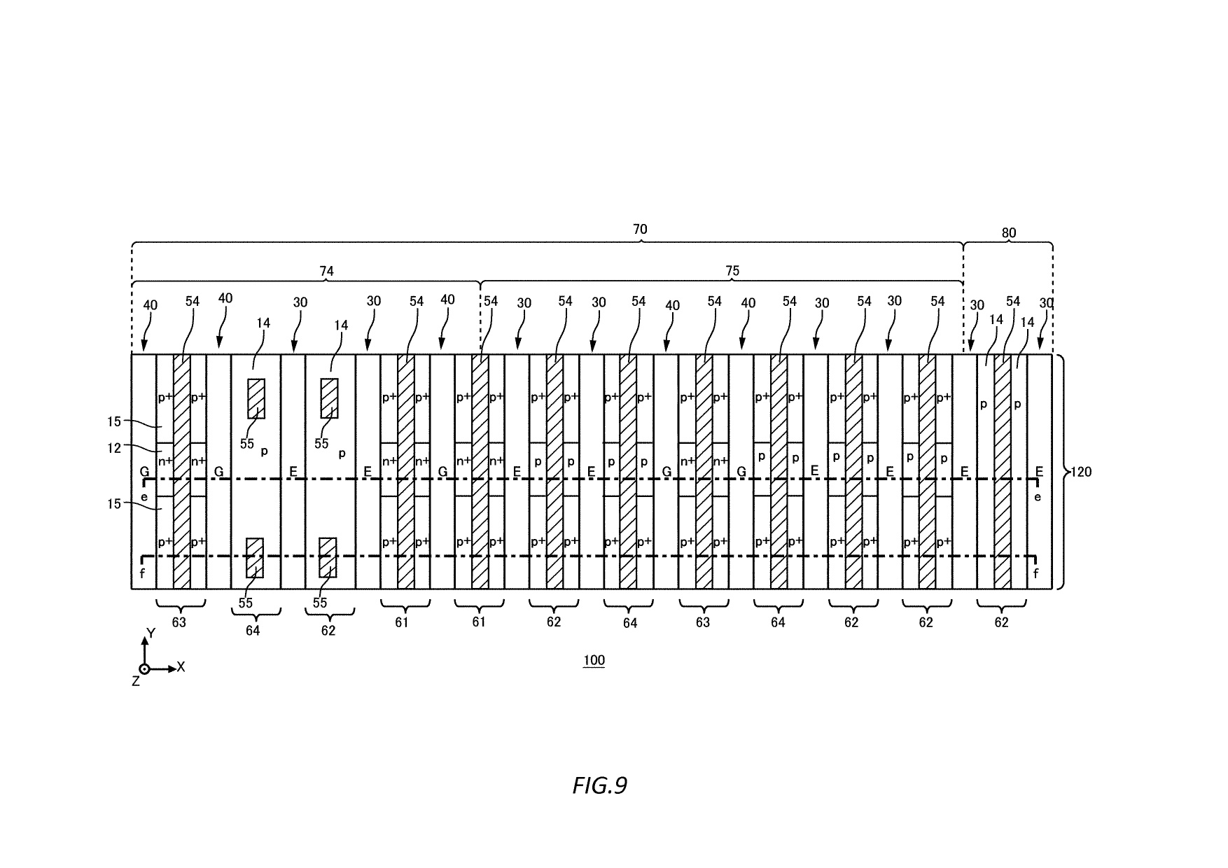

FIG. 9 is a top view illustrating another example of the semiconductor device 100. The transistor portion 70 of the present example is common with the example of FIG. 6 in that a group of trench portions formed of three gate trench portions 40 and four dummy trench portions 30 are regarded as a repeat unit to be arrayed in the X axis direction, but the array of the gate trench portions 40 and the dummy trench portions 30 in the repeat unit is different from the example of FIG. 6.

In the repeat unit of the trench portion of the present example, one gate trench portion 40, two dummy trench portions 30, two gate trench portions 40 and two dummy trench portions 30 are arrayed in order in the X axis direction.

In the present example, the mesa portion includes a fourth mesa portion 64 in addition to the first mesa portion 61, the second mesa portion 62 and the third mesa portion 63. In the present example, the fourth mesa portion 64 is a mesa portion sandwiched between one of two adjacent dummy trench portions and the adjacent gate trench portion. That is, in the present example, the fourth mesa portion 64 is common with the first mesa portion 61 in being sandwiched between the gate trench portion 40 and the dummy trench portion 30. In the present example, the fourth mesa portion 64 is adjacent to the third mesa portion 63 by sandwiching the gate trench portion 40 therebetween. The mesa portion of the transistor portion 70 is any of the first mesa portion 61, the second mesa portion 62, the third mesa portion 63, or the fourth mesa portion 64, and the mesa portion of the diode portion 80 of the present example is the second mesa portion 62. The width in the X axis direction of each mesa portion in the present example is the same.

In the present example, similar to FIG. 2A, the mesa portion may have the base region 14 in contact with the well region 11 in the end portion in the Y axis direction. Also, similar to FIG. 2B, the mesa portion may be separated from the well region 11 by the drift region 18. In the present example, similar to FIG. 2A and FIG. 2B, the gate trench portion 40 may have an edge portion 41 that connects the linear portion 39 and two linear portions 39. In the present example, similar to FIG. 2A and FIG. 2B, the dummy trench portion 30 may have an edge portion 31 that connects the linear portion 29 and two linear portions 29.

In the present example, the first mesa portion 61 has a structure similar to that of the first mesa portion 61 of FIG. 1 and FIG. 6. The emitter region 12 is provided in the first mesa portion 61 of the present example. In the present example, the first mesa portion 61 is in contact with the emitter electrode 52 by the contact holes 54.

The base region 14 is provided in the second mesa portion 62 provided in the main region 74 of the present example, similarly to the second mesa portion 62 of FIG. 1 and FIG. 6. However, a plurality of contact holes 55 are discretely provided in the Y axis direction above the second mesa portion 62 provided in the main region 74 of the present example. That is, the second mesa portion 62 provided in the main region 74 of the present example is in contact with the emitter electrode 52 in a limiting manner, unlike the floating mesa portion.

In the present example, the contact holes 55 may have structures similar to those of the contact holes 54. In the present example, the contact holes 55 may have the contact plug portion provided inside, which connects the emitter electrode 52 and the semiconductor substrate 10. The contact plug portion may have a plug formed of tungsten or the like, and a barrier metal including titanium, provided in a portion in contact with the semiconductor substrate 10. The barrier metal may have a titanium nitride layer, or may have a stacking structure of a titanium nitride layer and a titanium layer.

Similar to FIG. 1 and FIG. 6, the second mesa portion 62 provided in the boundary contact region 75 of the present example is provided with the base region 14 and the contact region 15 that are alternately arranged, and is in contact with the emitter electrode 52 by the contact holes 54.

In the present example, the third mesa portion 63 has a structure similar to that of the first mesa portion 61 of the present example. The emitter region 12 is provided in the third mesa portion 63 of the present example. In the present example, the third mesa portion 63 is in contact with the emitter electrode 52 by the contact holes 54.

In the present example, the fourth mesa portion 64 has a structure similar to that of the second mesa portion 62 of the present example. The base region 14 is provided in the fourth mesa portion 64 provided in the main region 74 of the present example. The plurality of contact holes 55 are discretely provided in the Y axis direction above the fourth mesa portion 64 provided in the main region 74 of the present example. The fourth mesa portion 64 provided in the boundary contact region 75 of the present example is provided with the base region 14 and the contact region 15 that are alternately arranged, and is in contact with the emitter electrode 52 by the contact holes 55.

The size of each of the contact holes 55 and the number of the contact holes 55 in each mesa portion may be properly determined. The area proportion of the contact holes 55 provided above the second mesa portion 62 and the fourth mesa portion 64 of the main region 74 of the present example is smaller than the area proportion of the contact holes 54 provided above the first mesa portion 61 and the third mesa portion 63 of the present example.

In this manner, in the main region 74 of the present example, the contact holes 54 are provided above the first mesa portion 61 and the third mesa portion 63, and the contact holes 55 are provided above the second mesa portion 62 and the fourth mesa portion 64. In contrast, in the boundary contact region 75 of the present example, the contact holes 54 are provided above all of the mesa portions. Therefore, in a top view of the semiconductor substrate, the area proportion of the contact holes 54 in the boundary contact region 75 of the present example is greater than the total area proportion of the contact holes 54 and the contact holes 55 in the main region 74.

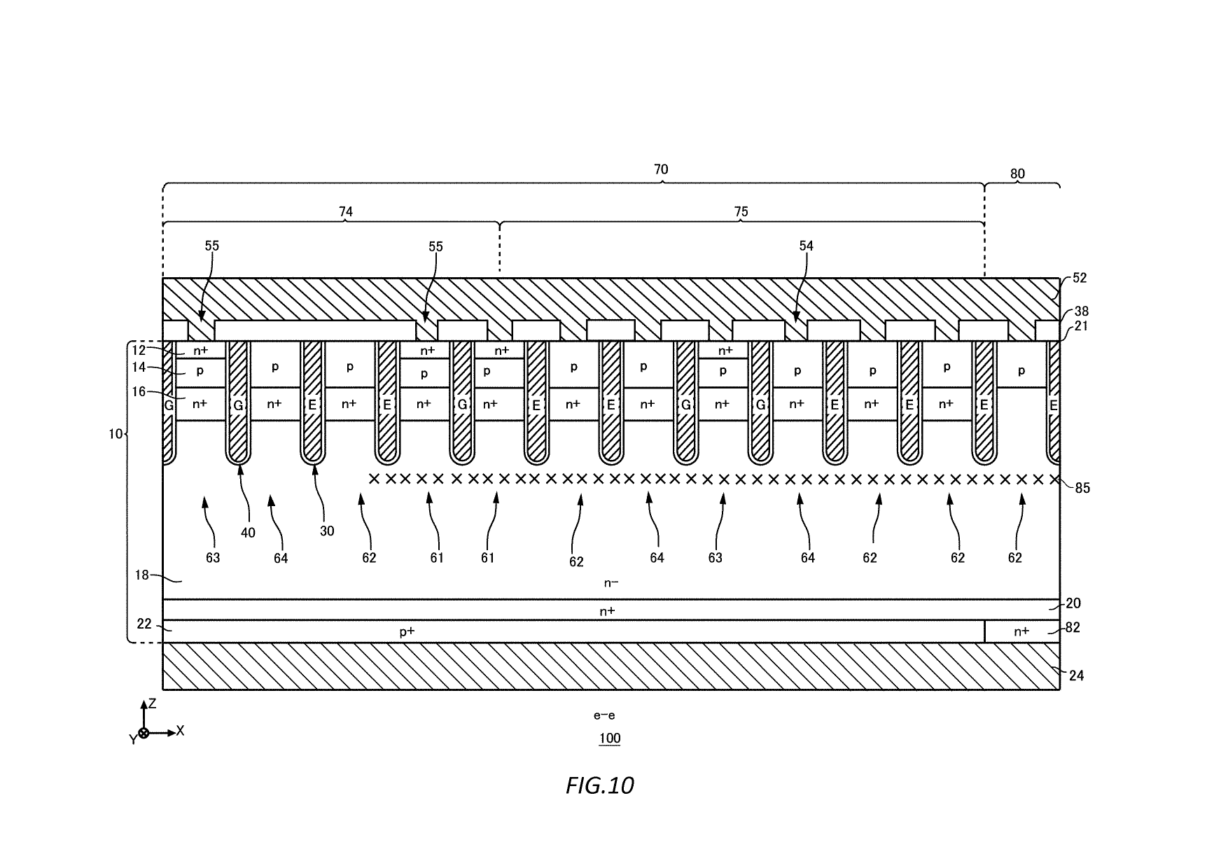

FIG. 10 illustrates an example of a cross section along the line e-e of FIG. 9. The cross section along the line e-e is an XZ plane passing through the emitter region 12. In the present example, the interlayer dielectric film 38 has contact holes 54 and contact holes 55. In the present example, the contact holes 54 are provided above the first mesa portion 61 and the third mesa portion 63 in the main region 74 of the transistor portion 70, and are provided above all the mesa portions in the boundary contact region 75 of the transistor portion 70. In the present example, the contact holes 54 are provided above all the mesa portions in the diode portion 80. In the present example, the contact holes 55 are provided above the second mesa portion 62 and the fourth mesa portion 64 in the main region 74 of the transistor portion 70.

If there are too many floating mesa portions, excess holes accumulate, causing self-charging and raising the gate potential. Therefore, even if the gate resistance is reduced, dV/dt does not decrease, and the saturation characteristics do not improve. In the present example, the second mesa portion 62 and the fourth mesa portion 64 of the main region 74 are not regarded as floating mesa portions, and self-charging is prevented by providing contact holes 55 discretely.

In the diode portion 80, the lifetime control region 85 including a lifetime killer is locally provided in the drift region 18. For example, the lifetime killer is a crystal defect formed at a predetermined depth position within the semiconductor substrate 10 by implanting helium ions, hydrogen ions (protons, deuterium ions), etc. The lifetime control region 85 promotes recombination between holes generated in the base region 14 during turn-off of the diode portion 80 and electrons implanted from the cathode region 82, thereby suppressing the peak current during reverse recovery.

In FIG. 10, peak positions in the Z axis direction of the concentration distribution of the lifetime killer are indicated by a symbol of "x". The lifetime control region 85 may be formed such that there are a plurality of peaks of the concentration distribution of the lifetime killer in the Z axis direction.

In the present example, the lifetime control region 85 is continuously provided across at least a part of the transistor portion 70 from the diode portion 80 in the X axis direction on the front surface 21 side of the semiconductor substrate 10. The lifetime control region 85 is provided to extend from the diode portion 80 to the main region 74 beyond the boundary contact region 75 of the transistor portion 70.

During conduction of the diode portion 80, a hole current flows not only from the base region 14 of the diode portion 80 but also from the base region 14 of the transistor portion 70 toward the cathode region 82. By extending the lifetime control region 85 from the diode portion 80 to at least a part of the transistor portion 70, carrier depletion is promoted, thereby reducing reverse recovery losses during turn-off.

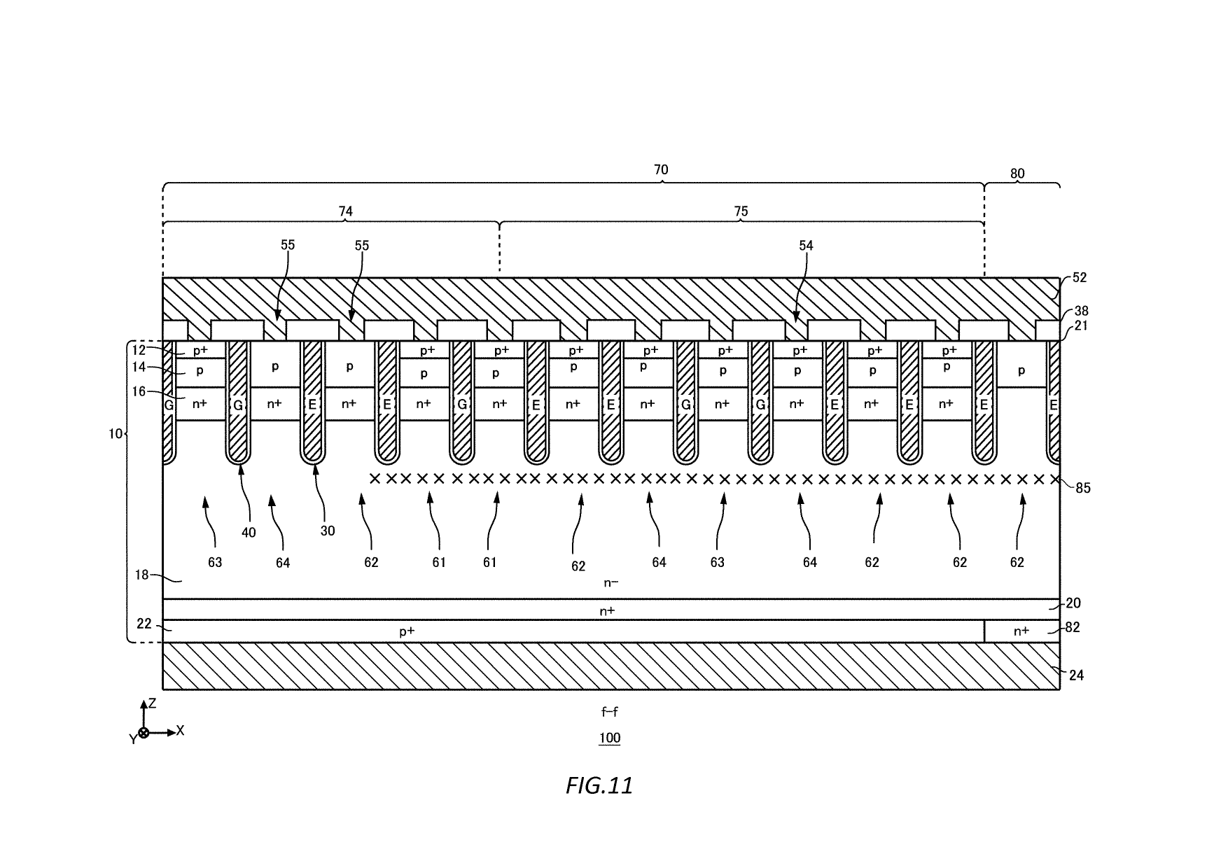

FIG. 11 illustrates an example of the cross section along the line f-f of FIG. 9. The cross section f-f is an XZ plane passing through the contact region 15. The cross section f-f passes through the contact holes 55 provided in the main region 74 of the transistor portion 70. The second mesa portion 62 and the fourth mesa portion 64 of the main region 74 are covered by the interlayer dielectric film 38 in FIG. 10, but in FIG. 11, they are connected to the emitter electrode 52 by the contact holes 55.

In the second mesa portion 62 and the fourth mesa portion 64 of the main region 74 in the present example, holes can be extracted from the contact holes 55 provided discretely. In this manner, it suppresses excessive accumulation of holes and prevents self-charging.

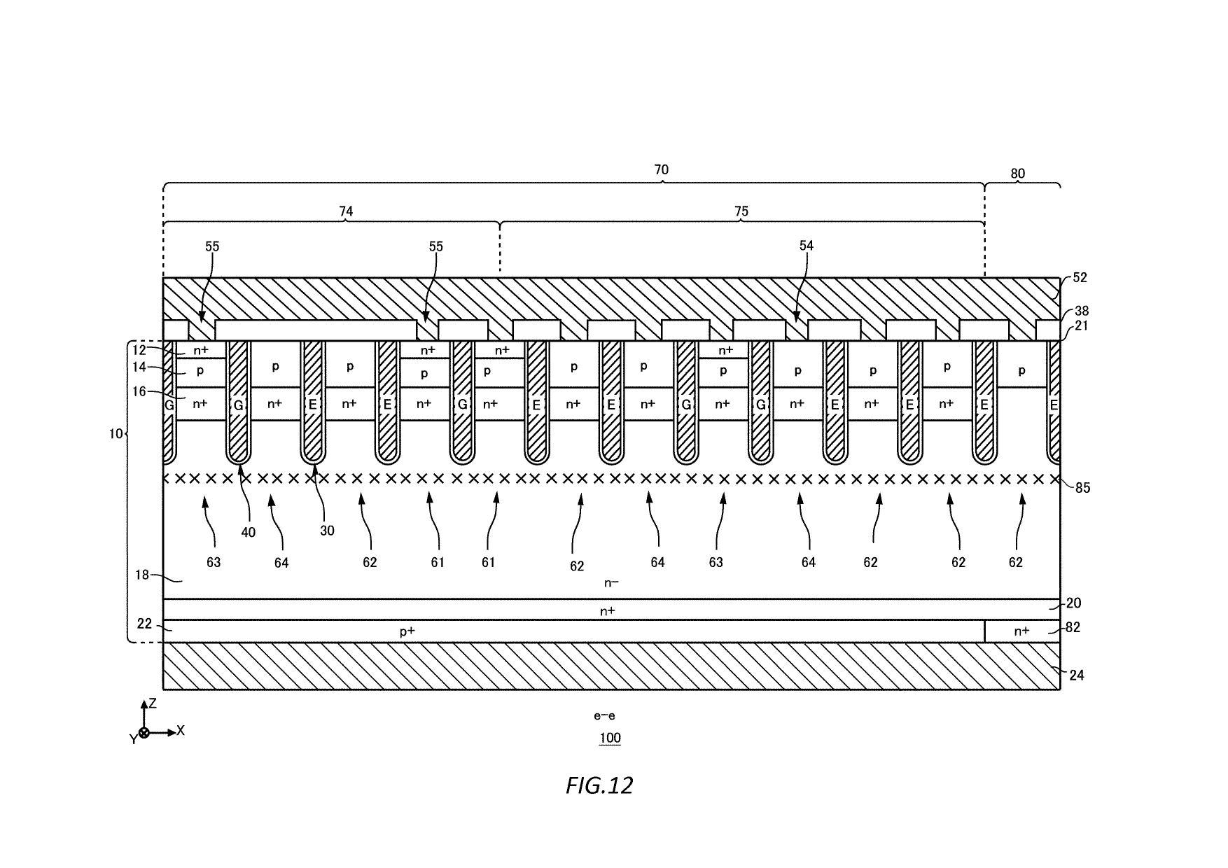

FIG. 12 illustrates another example of the cross section along the line e-e of FIG. 9. The lifetime control region 85 may be continuously provided throughout the transistor portion 70 from the diode portion 80 in the X axis direction on the front surface 21 side of the semiconductor substrate 10.

While the present invention has been described by way of the embodiments, the technical scope of the present invention is not limited to the above-described embodiments. It is apparent to persons skilled in the art that various alterations or improvements can be made to the above-described embodiments. It is also apparent from the description of the claims that the form to which such alterations or improvements are made can be included in the technical scope of the present invention.

It should be noted that the operations, procedures, steps, stages, and the like of each process performed by an apparatus, system, program, and method shown in the claims, the specification, or the drawings can be realized in any order as long as the order is not indicated by “prior to,” “before,” or the like and as long as the output from a previous process is not used in a later process. Even if the operation flow is described by using phrases such as "first" or "next" for the sake of convenience in the claims, specification, and drawings, it does not necessarily mean that the process must be performed in this order.

### EXPLANATION OF REFERENCES

10: semiconductor substrate; 11: well region; 12: emitter region; 14: base region; 15: contact region; 16: accumulation region; 18: drift region; 21: front surface; 22: collector region; 23: back surface; 24: collector electrode; 29: linear portion; 30: dummy trench portion; 31: edge portion; 32: dummy dielectric film; 34: dummy conductive portion; 38: interlayer dielectric film; 39: linear portion; 40: gate trench portion; 41: edge portion; 42: gate dielectric film; 44: gate conductive portion; 52: emitter electrode; 54: contact holes; 55: contact holes; 61: first mesa portion; 62: second mesa portion; 63: third mesa portion; 64: fourth mesa portion; 70: transistor portion; 74: main region; 75: boundary contact region; 80: diode portion; 82: cathode region; 85: lifetime control region; 100: semiconductor device; 120: active region; 131: gate runner.

What is claimed is:

1. A semiconductor device with a transistor portion and a diode portion, comprising:
a drift region of a first conductivity type provided on a semiconductor substrate;
a plurality of trench portions extending in a predetermined trench extending direction on a front surface of the semiconductor substrate;
a base region of a second conductivity type provided above the drift region;
an emitter region of the first conductivity type, provided above the drift region, with a doping concentration higher than that of the drift region;
a contact region of the second conductivity type, provided above the drift region, with a doping concentration higher than that of the base region; and
an interlayer dielectric film provided above the semiconductor substrate,
wherein the plurality of trench portions have a plurality of gate trench portions and a plurality of dummy trench portions; and
wherein the transistor portion has:
a main region; and
a boundary contact region, provided closer to the diode portion than to the main region, where an area proportion of contact holes provided in the interlayer dielectric film above a mesa portion is greater than that of the main region in a top view of the semiconductor substrate.

2. The semiconductor device according to claim 1, wherein:
the main region has at least one of a third mesa portion sandwiched between two adjacent gate trench portions among the plurality of gate trench portions, or a second mesa portion sandwiched between two adjacent dummy trench portions among the plurality of dummy trench portions; and
the second mesa portion and the third mesa portion provided in the main region are floating mesa portions covered by the interlayer dielectric film.

3. The semiconductor device according to claim 1, wherein a width in a trench array direction of the boundary contact region is 10% or more of a thickness of the semiconductor substrate and equal to or less than the thickness of the semiconductor substrate.

4. The semiconductor device according to claim 1, wherein a width in a trench array direction of the boundary contact region is 6 μm or more and 18.5 μm or less.

5. The semiconductor device according to claim 1, wherein an integrated concentration of p type dopants in the boundary contact region is higher than an integrated concentration of p type dopants in the main region.

6. The semiconductor device according to claim 1, wherein in the boundary contact region, contact holes are provided in the interlayer dielectric film above a second mesa portion sandwiched between two adjacent dummy trench portions among the plurality of dummy trench portions.

7. The semiconductor device according to claim 6, wherein the contact holes are provided to extend in the trench extending direction along the two adjacent dummy trench portions.

8. The semiconductor device according to claim 6, wherein in the boundary contact region, the contact region and the base region are alternately arrayed along the trench extending direction in an upper surface of a second mesa portion sandwiched between two adjacent dummy trench portions among the plurality of dummy trench portions.

9. The semiconductor device according to claim 1, wherein in the main region, a third mesa portion sandwiched between two adjacent gate trench portions among the plurality of gate trench portions, and a second mesa portion sandwiched between two adjacent dummy trench portions among the plurality of dummy trench portions are floating mesa portions covered by the interlayer dielectric film.

10. The semiconductor device according to claim 9, wherein in the boundary contact region, contact holes are provided in the interlayer dielectric film above a second mesa portion sandwiched between two adjacent dummy trench portions among the plurality of dummy trench portions.

11. The semiconductor device according to claim 9, wherein in the boundary contact region, a third mesa portion sandwiched between two adjacent gate trench portions among the plurality of gate trench portions is a floating mesa portion covered by the interlayer dielectric film.

12. The semiconductor device according to claim 2, comprising
a well region of the second conductivity type, provided on a front surface of the semiconductor substrate enclosing the transistor portion and the diode portion, with a doping concentration higher than that of the base region,
wherein the floating mesa portion is separated from the well region by the drift region in an end portion of the trench extending direction.

13. The semiconductor device according to claim 1, wherein in the main region, a plurality of contact holes are discretely provided in the trench extending direction in the interlayer dielectric film above a second mesa portion, which is sandwiched between two adjacent dummy trench portions among the plurality of trench portions, and a fourth mesa portion sandwiched between one of the two adjacent dummy trench portions and an adjacent gate trench portion.

14. The semiconductor device according to claim 13, wherein in the main region, in the interlayer dielectric film above a third mesa portion, which is sandwiched between two adjacent gate trench portions among the plurality of gate trench portions, contact holes that extend in the trench extending direction along the two adjacent gate trench portion are provided.

15. The semiconductor device according to claim 13, wherein contact holes that extend in the trench extending direction along the plurality of trench portions are provided in the interlayer dielectric film above a mesa portion of the boundary contact region.

16. The semiconductor device according to claim 13, wherein in the plurality of trench portions, a gate trench portion, two dummy trench portions, two gate trench portions and two dummy trench portions are arrayed in order in a trench array direction.

17. The semiconductor device according to claim 1, wherein in the boundary contact region, contact holes that extend in the trench extending direction along a gate trench portion and a dummy trench portion adjacent to each other are provided in the interlayer dielectric film above a first mesa portion sandwiched between the gate trench portion and the dummy trench portion adjacent to each other among the plurality of trench portions.

18. The semiconductor device according to claim 1, wherein a width in a trench array direction of a mesa portion in the main region is identical to a width in a trench array direction of a mesa portion in the boundary contact region.

19. The semiconductor device according to claim 1, wherein a width in a trench array direction of a mesa portion in the transistor portion is identical to a width in a trench array direction of a mesa portion in the diode portion.

20. The semiconductor device according to claim 1, comprising a lifetime control region provided on a front surface side of the semiconductor substrate, which extends from the diode portion to the main region beyond the boundary contact region in a trench array direction.
